(19) United States
(12) Patent Application Publication
(10) Pub. No.: US 2011/0209751 A1
(43) Pub. Date: Sep. 1, 2011

(54) PASTE COMPOSITION FOR ELECTRODE AND PHOTOVOLTAIC CELL

(75) Inventors: Takeshi Nojiri, Tsukuba-shi (JP); Masato Yoshida, Tsukuba-shi (JP); Mitsunori Iwamuro, Tsukuba-shi (JP); Shuuichirou Adachi, Tsukuba-shi (JP); Keiko Kizawa, Tsukuba-shi (JP); Takuya Aoyagi, Hitachi-shi (JP); Hiroki Yamamoto, Hitachi-shi (JP); Takashi Naito, Hitachi-shi (JP); Takahiko Kato, Hitachi-shi (JP)

(73) Assignee: HITACHI CHEMICAL COMPANY, LTD.

(21) Appl. No.: 13/013,293

(22) Filed: Jan. 25, 2011

Related U.S. Application Data
(60) Provisional application No. 61/298,154, filed on Jan. 25, 2010.

(51) Int. Cl. H01L 31/0224; H01B 1/22

(52) U.S. Cl. 136/256; 252/512; 252/514

(57) ABSTRACT

The paste composition for an electrode according to the present invention includes metal particles containing copper as a main component, a flux, glass particles, a solvent, and a resin. Further, a photovoltaic cell according to the present invention has an electrode formed by using the paste composition for an electrode.

### CROSS-REFERENCE TO RELATED APPLICATIONS

This application claims priority under 35 U.S.C. 119(e) to Provisional U.S. Patent Application No. 61/298,154, filed Jan. 25, 2010, the disclosure of which is incorporated by reference herein.

### BACKGROUND OF THE INVENTION

1. Field of the Invention

The present invention relates to a paste composition for an electrode and a photovoltaic cell.

2. Description of the Related Art

Generally, a photovoltaic cell is provided with a surface electrode, in which the wiring resistance or contact resistance of the surface electrode is related to a voltage loss associated with conversion efficiency, and further, the wiring width or shape has an influence on the amount of the incident sunlight (see, for example, “Sunlight Power Generation, Newest Technology and Systems”, edited by Yoshihiro Hamakawa, CMC Books, 2001, p. 26-27).

The surface electrode of a photovoltaic cell is usually formed in the following manner. That is, a conductive composition is applied onto an n-type semiconductor layer, which is formed by thermally diffusing phosphorous and the like at a high temperature on the light-receiving surface side of a p-type silicon substrate, by screen printing or the like, and sintered at a high temperature of 800 to 900° C., thereby forming a surface electrode. This conductive composition for forming the surface electrode includes conductive metal powders, glass particles, various additives, and the like.

As the conductive metal powders, silver powders are generally used, but the use of metal powders other than silver powders has been investigated for various reasons. For example, a conductive composition capable of forming an electrode for a photovoltaic cell, including silver and aluminum, is disclosed (see, for example, Japanese Patent Application Laid-Open (JP-A) No. 2006-313744). In addition, a composition for forming an electrode, including metal nanoparticles including silver and metal particles such as copper other than silver, is disclosed (see, for example, JP-A No. 2008-226816).

### SUMMARY OF THE INVENTION

Silver, which is generally used to form an electrode, is a noble metal and, in view of problems regarding resources and also from the viewpoint that the ore is expensive, proposals for a paste material which replaces the silver-containing conductive composition (silver-containing paste) are desirable. As a promising material for replacing silver, there is copper which is employed in semiconductor wiring materials. Copper is abundant as a resource and the cost of the metal is inexpensive, about as low as one hundredth the cost of silver. However, copper is a material susceptible to oxidation at high temperatures of 200° C. or higher. For example, in the composition for forming an electrode described in JP-A No. 2008-226816, in order to form the electrode by sintering of the composition it is necessary to conduct a special process in which the composition is sintered under an atmosphere of nitrogen or the like.

It is an object of the present invention to provide a paste composition for an electrode, which is capable of forming an electrode having a low resistivity by inhibiting the formation of an oxide film of copper at a time of sintering, and a photovoltaic cell having an electrode in which the electrode is formed by using the paste composition for an electrode.

A first embodiment according to the present invention is a paste composition for an electrode, including metal particles containing copper as a main component, a flux, glass particles, a solvent and a resin. The paste composition for an electrode preferably further contains silver particles. The metal particles having copper as a main component are preferably at least one selected from phosphorous-containing copper alloy particles, silver-coated copper particles, and copper particles surface-treated with at least one selected from the group consisting of triazole compounds, saturated fatty acids, unsaturated fatty acids, inorganic metal compound salts, organic metal compound salts, polyaniline-based resins, and metal alkoxides. The flux is preferably at least one selected from fatty acids, boric acid compounds, fluoride compounds, and fluoroborate compounds. The glass particles preferably contain an oxide including phosphorous.

A second embodiment of the present invention is a photovoltaic cell having an electrode, in which the electrode is formed by sintering the paste composition for an electrode, which was applied to a silicon substrate.

According to the present invention, there is provided a paste composition for an electrode, which is capable of forming an electrode having a low resistivity by inhibiting the formation of an oxide film of copper even at a time of sintering by the addition of a flux, and a photovoltaic cell having an electrode which is formed by using the paste composition for an electrode.

### BRIEF DESCRIPTION OF THE DRAWINGS

FIG. 1 is a cross-sectional view of the photovoltaic cell according to the present invention.

FIG. 2 is a plane view showing the light-receiving surface side of the photovoltaic cell according to the present invention.

FIG. 3 is a plane view showing the back surface side of the photovoltaic cell according to the present invention.

FIG. 4A is a perspective view showing the AA cross-sectional constitution of the cell back contact-type photovoltaic cell according to the present invention.

FIG. 4B is a plane view showing the back surface side electrode structure of the cell back contact-type photovoltaic cell according to the present invention.

### DETAILED DESCRIPTION OF THE INVENTION

Hereinbelow, the embodiments of the present invention will be described in detail. Furthermore, in the present specification, “to” denotes a range including each of the minimum value and the maximum value of the values described before and after the reference.

### <Paste Composition for Electrode>

The paste composition for an electrode of the present invention includes at least one kind of metal particles having copper as a main component, at least one flux, at least one kind of glass particles, at least one solvent, and at least one resin.

By adopting such a constitution, it is possible to form an electrode having a low resistivity by inhibiting the production of an oxide film of copper even at a time of sintering.

### (Metal Particles Having Copper as Main Component)

In the present invention, the metal particles having copper as a main component (hereinafter referred to as the “copper-containing particles” in some cases) mean the metal particles in which the content of the copper components per one metal particle is 50% by mass or more.

The copper particles may consist of pure copper, substantially copper, also including other atoms in an amount which dose not impair the effect of the invention. Also the copper particles may consist of copper and other components which impart copper with oxidation resistance.

Examples of other atoms in the metal particle substantially consisting of copper include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the copper-containing particles can be, for example, 3% by mass or less in the copper-containing particles, and from the viewpoint of the oxidation resistance and the low resistivity, it is preferably 1% by mass or less.

Regarding the metal particles which include copper and other components for imparting copper with oxidation resistance, a peak temperature of an exothermic peak showing a maximum area is preferably 280° C. or higher, more preferably from 280 to 800° C., and even more preferably from 350 to 750° C., by measurement in the simultaneous ThermoGravimetry/Differential Thermal Analysis (TG-DTA).

By using the copper-containing particle imparted with oxidation resistance, the oxidation of the metal copper can be inhibited at a time of sintering, thereby forming an electrode having a low resistivity. The simultaneous ThermoGravimetry/Differential Thermal Analysis is typically carried out using a ThermoGravimetry/Differential Thermal Analysis analyzer (TG/DTA-6200 type, manufactured by SII Nano Technology Inc.) as a measurement device.

Specific examples of the copper-containing particles, which have a peak temperature in the exothermic peak showing a maximum area of 280° C. or higher in the simultaneous ThermoGravimetry/Differential Thermal Analysis (TG-DTA), include phosphorous-containing copper alloy particles, silver-coated copper particles, and surface-treated copper particles.

The copper-containing particles may be used singly or in combination of two or more kinds thereof.

The particle diameter of the copper-containing particles is not particularly limited, and it is preferably from 0.4 to 10 μm, and more preferably from 1 to 7 μm in terms of a particle diameter when the cumulative mass is 50% (hereinafter abbreviated as “D50% in some cases). By setting the particle diameter to 0.4 μm or more, the oxidation resistance is improved more effectively. Further, by setting the particle diameter to 10 μm or less, the contact area at which the copper-containing particles contact each other in the electrode increases, whereby the resistivity is reduced more effectively. The particle diameter of the copper-containing particle is measured by means of a MICROTRAC particle size distribution analyzer (MT3300 type, manufactured by Nikkiso Co., Ltd.).

In addition, the shape of the copper-containing particle is not particularly limited, and it may be any one of a spherical shape, a flat shape, a block shape, a plate shape, a scale-like shape, and the like. From the viewpoint of oxidation resistance and low resistivity, it is preferably a spherical shape, a flat shape, or a plate shape.

The content of the copper-containing particles, or the total content of the copper-containing particles and the silver particles when including silver particles as described later can be, for example, from 70 to 94% by mass, and from the viewpoint of oxidation resistance and low resistivity, preferably from 72 to 90% by mass, and more preferably from 74 to 88% by mass, based on the paste composition for an electrode.

### —Phosphorous-Containing Copper Alloy Particles—

As the phosphorous-containing copper alloy, a brazing material called copper phosphorus brazing (phosphorous concentration: approximately 7% by mass) is known. The copper phosphorus brazing is used as a copper to copper bonding agent. In the present invention, the phosphorous-containing copper alloy particles is used as the copper-containing particles in the paste composition for an electrode, whereby the oxidation resistance is excellent and an electrode having a low resistivity can be formed. Furthermore, it becomes possible to sinter the electrode at a low temperature, and as a result, an effect of reducing a process cost can be attained.

In the present invention, the content of phosphorous included in the phosphorous-containing copper alloy is preferably a content such that the peak temperature of the exothermic peak showing a maximum area becomes 280° C. or higher in the simultaneous ThermoGravimetry/Differential Thermal Analysis. Specifically, the content of phosphorous included in the phosphorous-containing copper alloy is preferably from 0.01 to 8% by mass, more preferably from 0.5 to 7.8% by mass, and even more preferably from 1 to 7.5% by mass, based on the total mass of the phosphorous-containing copper alloy.

By setting the content of phosphorous included in the phosphorous-containing copper alloy to 8% by mass or less, a lower resistivity can be attained, and also, the productivity of the phosphorous-containing copper alloy is improved. Further, by setting the content of phosphorous included in the phosphorous-containing copper alloy to 0.01% by mass or more, more excellent acid resistance can be exhibited.

The phosphorous-containing copper alloy particle is an alloy including copper and phosphorous, and it may include other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the phosphorous-containing copper alloy particles can be, for example, 3% by mass or less in the phosphorous-containing copper alloy particles, and from the viewpoint of the oxidation resistance and the low resistivity, it is preferably 1% by mass or less.

The particle diameter of the phosphorous-containing copper alloy particles is not particularly limited, and it is preferably from 0.4 to 10 μm, and more preferably from 1 to 5 μm in terms of a particle diameter when the cumulative mass is 50% (hereinafter abbreviated as “D50% in some cases). By setting the particle diameter to 0.4 μm or more, the oxidation resistance is improved more effectively. Further, by setting the particle diameter to 10 μm or less, the contact area at which the phosphorous-containing copper alloy particles contact each other in the electrode increases, whereby the resistivity is reduced more effectively.

In addition, the shape of the phosphorous-containing copper alloy particle is not particularly limited, and it may be any one of a spherical shape, a flat shape, a block shape, a plate shape, a scale-like shape, and the like. From the viewpoint of oxidation resistance and low resistivity, it is preferably a spherical shape, a flat shape, or a plate shape.

The phosphorous copper alloy can be prepared by a typically used method. Further, the phosphorous-containing copper alloy particles can be prepared by a general method for preparing metal powders using a phosphorous-containing copper alloy that is prepared so as to give a desired phosphorous content with a general method, for example, a water atomization method. The water atomization method is described in Handbook of Metal (Maruzen CO., LTD. Publishing Dept.) or the like.

Specifically, for example, a desired phosphorous-containing copper alloy particle can be prepared by dissolving a phosphorous-containing copper alloy, forming a powder by a nozzle spray, drying the obtained powders, and classifying them. Further, a phosphorous-containing copper alloy particle having a desired particle diameter can be prepared by appropriately selecting the classification condition.

The content of the phosphorous-containing copper alloy particles, or the total content of the phosphorous-containing copper alloy particles and the silver particles when including silver particles as described later can be, for example, from 70 to 94% by mass, and from the viewpoint of oxidation resistance and low resistivity, preferably from 72 to 90% by mass, and more preferably from 74 to 88% by mass, based on the paste composition for an electrode of the present invention.

Furthermore, in the present invention, the phosphorous-containing copper alloy particles may be used singly or in combination of two or more kinds thereof. In addition, they may be used in combination with copper-containing particles, other than the phosphorous copper alloy particles.

Moreover, in the present invention, from the viewpoint of the oxidation resistance and the low resistivity of the electrode, it is preferable that the phosphorous-containing copper alloy particles having a phosphorous content of from 0.01 to 8% by mass be contained in an amount of from 70 to 94% by mass based on the paste composition for an electrode, and it is more preferable that the phosphorous-containing copper alloy particles having a phosphorous content of from 1 to 7.5% by mass be contained in an amount of 74 to 88% by mass, based on the paste composition for an electrode

### —Silver-Coated Copper Particles—

The silver-coated copper particle in the present invention may be any one in which at least a part of the copper particle surface is coated with silver. By using the silver-coated copper particles as the copper-containing particles included in the paste composition for an electrode of the present invention, the oxidation resistance is excellent and an electrode having a low resistivity can be formed. Further, by coating the copper particle with silver, the interfacial resistance between the copper particle and the silver particle is reduced, and thus, an electrode having a resistivity further reduced can be formed. In addition, when forming a paste composition, if moisture is incorporated, an effect whereby the oxidation of copper at room temperature can be inhibited by using the silver-coated copper particles and the pot life can be enhanced can be obtained.

The coating amount of silver (silver content) in the silver-coated copper particles is preferably a coating amount (silver content) such that the peak temperature of the exothermic peak showing a maximum area is 280° C. or higher in the simultaneous ThermoGravimetry/Differential Thermal Analysis. Specifically, the coating amount of silver is 1% by mass or more based on the total mass of the silver-coated copper particles. From the viewpoint of the oxidation resistance and the low resistivity of the electrode, it is preferably from 1 to 88% by mass, more preferably from 3 to 80% by mass, and even more preferably from 5 to 75% by mass, based on the total mass of the silver-coated copper particles.

Furthermore, the particle diameter of the silver-coated copper particle is not particularly limited, and it is preferably from 0.4 to 10 μm, and more preferably from 1 to 7 μm in terms of a particle diameter when the cumulative mass is 50% (hereinafter abbreviated as “D50% in some cases). By setting the particle diameter to 0.4 μm or more, the oxidation resistance is improved more effectively. Further, by setting the particle diameter to 10 μm or less, the contact area at which the silver-coated copper particles contact each other in the electrode increases and, thus, the resistivity is reduced more effectively.

In addition, the shape of the silver-coated copper particle is not particularly limited, and it may be any one of an approximately spherical shape, a flat shape, a block shape, a plate shape, a scale-like shape, and the like. From the viewpoint of oxidation resistance and low resistivity, it is preferably an approximately spherical shape, a flat shape, or a plate shape.

Copper constituting the silver-coated copper particle may contain other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the silver-coated copper particle can be, for example, 3% by mass or less in the silver-coated copper particle, and from the viewpoint of the oxidation resistance and the low resistivity, it is preferably 1% by mass or less.

Furthermore, it is also preferable that the silver-coated copper particle be one obtained by coating the above-described phosphorous-containing copper alloy with silver. Consequently, the oxidation resistance is further improved, and thus, the resistivity of the electrode to be formed is further reduced.

Details on the phosphorous-containing alloy for the silver-coated copper particles and preferred embodiments thereof are the same as for the above-described phosphorous-containing alloy.

The method for forming the silver-coated copper particles is not particularly limited as long as it is a forming method in which at least a part of the surface of the copper particle (preferably phosphorous-containing copper alloy particles) can be coated with silver. For example, copper powders (or phosphorous-containing copper alloy powders) are dispersed in an acidic solution such as sulfuric acid, hydrochloric acid, and phosphoric acid, and then a chelator is added to the copper powder dispersion, thereby preparing a copper powder slurry. By adding a silver ion solution to the copper powder slurry obtained, a silver layer can be formed on the copper powder surface by a substitution reaction.

The chelator is not particularly limited, and, for example, ethylene diamine tetraacetate, triethylene diamine, diethylene triamine pentaacetate, imino diacetate, or the like can be used. Further, as the silver ion solution, for example, a silver nitrate solution, or the like can be used.

The content of the silver-coated copper particles, or the total content of the silver-coated copper particles and the silver particles when including silver particles as described later can be, for example, from 70 to 94% by mass, and from the viewpoint of oxidation resistance and low resistivity, preferably from 72 to 90% by mass, and more preferably from 74 to 88% by mass, based on the paste composition for an electrode of the present invention.

Furthermore, in the present invention, the silver-coated copper particles may be used singly or in combination of two or more kinds thereof. In addition, they may be used in combination with copper-containing particles, other than the silver-coated copper particles.

In the present invention, from the viewpoint of the oxidation resistance and the low resistivity of the electrode, it is preferable that the silver-coated copper particles having a silver content of from 1 to 88% by mass based on the total mass of the silver-coated copper particles be contained in an amount of from 70 to 94% by mass (the total content of the silver-coated copper particles and the silver particles when including the silver particles as described later) based on the paste composition for an electrode, and it is more preferable that the silver-coated copper particles having a silver content of from 5% by mass to 75% by mass be contained in an amount of from 74 to 88% by mass (the total content of the silver-coated copper particles and the silver particles when including the silver particles as described later) based on the paste composition for an electrode.

Furthermore, it is preferable that the silver-coated phosphorous-containing copper alloy particles having a silver content of from 1% by mass to 88% by mass and a phosphorous content from 0.01 to 8% by mass be contained in an amount of from 70 to 94% by mass (the total content of the silver-coated phosphorous-containing copper alloy particles and the silver particles when including the silver particles as described later) based on the paste composition for an electrode, and it is more preferable that the silver-coated phosphorous-containing copper alloy particles having a silver content of from 5% by mass to 75% by mass and a phosphorous content from 1 to 7.5% by mass be contained in an amount of from 74 to 88% by mass (the total content of the silver-coated phosphorous-containing copper alloy particles and the silver particles when including the silver particles as described later) based on the paste composition for an electrode.

### —Surface-Treated Copper Particles—

The copper-containing particles in the present invention are also preferably copper particles that are surface-treated with at least one selected from a group consisting of a triazole compound, a saturated fatty acid, an unsaturated fatty acid, an inorganic metal compound salt, an organic metal compound salt, a polyaniline-based resin, and a metal alkoxide (hereinafter referred to as the “surface treatment agent”), and more preferably copper particles that are surface-treated with at least one selected from a group consisting of a triazole compound, a saturated fatty acid, an unsaturated fatty acid, and an inorganic metal compound salt.

By using the copper particles which are surface-treated with at least one kind of surface treatment agent as the copper-containing particles included in the paste composition for an electrode of the present invention, the oxidation resistance is excellent and an electrode having a low resistivity can be formed. In addition, when forming a paste composition, if moisture is incorporated, an effect whereby oxidation of copper at room temperature can be inhibited by using the surface treatment agent and the pot life can be enhanced can be obtained.

Furthermore, in the present invention, the surface treatment agents may be used singly or in combination of two or more kinds thereof.

In the present invention, the surface-treated copper particles are surface-treated with at least one selected from the group consisting of a triazole compound, a saturated fatty acid, an unsaturated fatty acid, an inorganic metal compound salt, an organic metal compound salt, a polyaniline-based resin, and a metal alkoxide. If necessary, other surface treatment agents may be used together therewith.

Examples of the triazole compound in the surface treatment include benzotriazole and triazole. Further, examples of the saturated fatty acid in the surface treatment include enanthic acid, caprylic acid, pelargonic acid, capric acid, undecylic acid, lauric acid, tridecyl acid, myristic acid, pentadecyl acid, stearic acid, nonadecanoic acid, arachidic acid, and behenic acid. Further, examples of the unsaturated fatty acid in the surface treatment include acrylic acid, methacrylic acid, crotonic acid, isocrotonic acid, undecylenic acid, oleic acid, elaidic acid, cetoleic acid, brassidic acid, erucic acid, sorbic acid, linoleic acid, linolenic acid, and arachidonic acid.

Moreover, examples of the inorganic metal compound salt in the surface treatment include sodium silicate, sodium stannate, tin sulfate, zinc sulfate, sodium zincate, zirconium nitrate, sodium zirconate, zirconium oxide chloride, titanium sulfate, titanium chloride, and potassium oxalate titanate. Further, examples of the organic metal compound salt in the surface treatment include lead stearate, lead acetate, a p-cumylphenyl derivative of tetraalkoxyzirconium, and a p-cumylphenyl derivative of tetraalkoxytitanium. In addition, examples of the metal alkoxide in the surface treatment include titanium alkoxide, zirconium alkoxide, lead alkoxide, silicon alkoxide, tin alkoxide, and indium alkoxide.

Examples of other surface treatment agents include dodecyl benzene sulfonic acid. Further, when stearic acid or lead stearate is used as the surface treatment agent, at least one kind of stearic acid and lead stearate can be used in combination with lead acetate as the surface treatment agent to form an electrode having further improved oxidation resistance and thus having a lower resistivity.

As the surface-treated copper particles in the present invention, any copper particles in which at least a part of the surface of the copper particles is coated with at least one kind of the surface treatment agents is suitable. The content of the surface treatment agent contained in the surface-treated copper particle is preferably a content such that the peak temperature of the exothermic peak showing a maximum area is 280° C. or higher in the simultaneous ThermoGravimetry/Differential Thermal Analysis. Specifically, the content is from 0.01% by mass or more, based on the total mass of the surface-treated copper particles. From the viewpoint of the oxidation resistance and the low resistivity of the electrode, it is preferably from 0.01 to 10% by mass, and more preferably from 0.05 to 8% by mass, based on the mass of the surface-treated copper particles.

Copper constituting the surface-treated copper particles may contain other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the surface-treated copper particle can be, for example, 3% by mass or less in the surface-treated copper particle, and from the viewpoint of the oxidation resistance and the low resistivity, it is preferably 1% by mass or less.

Furthermore, it is also preferable that the surface-treated copper particles be those obtained by subjecting the above-described phosphorous-containing copper alloy to a surface treatment. Consequently, the oxidation resistance is further improved, and thus, the resistivity of the electrode to be formed is further reduced.

Details on the phosphorous-containing alloy for the surface-treated copper particles and preferred embodiments thereof are the same as for the above-described phosphorous-containing alloy.

Furthermore, the particle diameter of the surface-treated copper particle is not particularly limited, and it is preferably from 0.4 to 10 μm, and more preferably from 1 to 7 μm in terms of a particle diameter when the cumulative mass is 50% (hereinafter abbreviated as “D50% in some cases). By setting the particle diameter to 0.4 μm or more, the oxidation resistance is improved more effectively. Further, by setting the particle diameter to 10 μm or less, the contact area at which the surface-treated copper particles contact each other in the electrode increases and thus, the resistivity is reduced more effectively.

In addition, the shape of the surface-coated copper particle is not particularly limited, and it may be any one of an approximately spherical shape, a flat shape, a block shape, a plate shape, a scale-like shape, and the like. From the viewpoint of oxidation resistance and low resistivity, it is preferably an approximately spherical shape, a flat shape, or a plate shape.

The method for the surface treatment of the copper particles using a surface treatment agent can be appropriately selected according to the surface treatment agent to be used. For example, a surface treatment agent is dissolved in a solvent capable of dissolving the surface treatment agent to be prepared for a surface treatment solution, and copper particles are immersed therein and then dried, whereby at least a part of the surface of the copper particles can be coated with the surface treatment agent.

The solvent capable of dissolving the surface treatment agent can be appropriately selected depending on the surface treatment agent. Examples of the solvent include water; alcohol-based solvents such as methanol, ethanol, and isopropanol; glycol-based solvents such as ethylene glycol monoethyl ether; carbitol-based solvents such as diethylene glycol monobutyl ethe; and carbitol acetate-based solvents such as diethylene glycol monoethyl ether acetate.

Specifically, for example, when benzotriazole, triazole, or dodecyl benzene sulfonic acid is used as the surface treatment agent, a surface treatment solution can be prepared using the alcohol-based solvent, thereby subjecting the copper particles to a surface treatment.

In addition, when stearic acid or lead stearate is used as the surface treatment agent, a surface treatment solution can be prepared using the alcohol-based solvent.

The concentration of the surface treatment agent in the surface treatment solution can be appropriately selected depending on the kind of the surface treatment agent used and a desired extent of the surface treatment. For example, the concentration can be from 1 to 90% by mass, and preferably from 2 to 85% by mass.

The content of the surface-treated copper particles, or the total content of the surface-treated copper particles and the silver particles when including silver particles as described later can be, for example, from 70 to 94% by mass, and from the viewpoint of oxidation resistance and low resistivity, preferably from 72 to 90% by mass, and more preferably from 74 to 88% by mass, based on the paste composition for an electrode of the present invention.

Furthermore, in the present invention, the surface-treated copper particles may be used singly or in combination of two or more kinds thereof. In addition, they may be used in combination with copper-containing particles in addition to the surface-treated copper particles.

In the present invention, from the viewpoint of the oxidation resistance and the low resistivity of the electrode, it is preferable that the copper particles, in which at least one selected from the group consisting of a triazole compound, a saturated fatty acid, an unsaturated fatty acid, an inorganic metal compound salt, an organic metal compound salt, a polyaniline-based resin, and a metal alkoxide is subjected to 0.01 to 10% by mass surface treatment, be contained in an amount of 70 to 94% by mass (the total content of the surface-treated copper particles and the silver particles when including the silver particles as described later) based on the paste composition for an electrode, and it is more preferable that the copper particles, in which at least one selected from the group consisting of a triazole compound, a saturated fatty acid, an unsaturated fatty acid, and an inorganic metal compound salt is subjected to 0.05 to 8% by mass surface treatment, be contained in an amount of 74 to 88% by mass (the total content of the surface-treated copper particles and the silver particles when including the silver particles as described later) based on the paste composition for an electrode.

Furthermore, it is preferable that the surface-treated phosphorous-containing copper alloy particles, in which at least one selected from the group consisting of a triazole compound, a saturated fatty acid, an unsaturated fatty acid, an inorganic metal compound salt, an organic metal compound salt, a polyaniline-based resin, and a metal alkoxide is subjected to from 0.01 to 10% by mass surface treatment and the phosphorous content is 8% by mass or less, be contained in an amount of from 70 to 94% by mass (the total content of the surface-treated phosphorous-containing copper alloy particles and the silver particles when including the silver particles as described later) based on the paste composition for an electrode, and it is more preferable that the surface-treated phosphorous-containing copper alloy particles, in which at least one selected from the group consisting of a triazole compound, a saturated fatty acid, an unsaturated fatty acid, and an inorganic metal compound salt is subjected to from 0.05 to 8% by mass surface treatment, and the phosphorous content is from 1 to 7.5% by mass or less, be contained in an amount of from 74 to 88% by mass (the total content of the surface-treated phosphorous-containing copper alloy particles and the silver particles when including the silver particles as described later) based on the paste composition for an electrode.

### (Glass Particles)

The paste composition for an electrode according to the present invention includes at least one kind of glass particle. By incorporating glass particles in the paste composition for an electrode, a silicon nitride film which is an anti-reflection film is removed by a so-called fire-through at an electrode-forming temperature, and an ohmic contact between the electrode and the silicon substrate is formed.

As the glass particles, any known glass particles in the related art may be used without a particular limitation, provided the glass particles are softened or melted at an electrode-forming temperature to contact with the silicon nitride, thereby oxidizing the silicon nitride and then incorporating the oxidized silicon dioxide thereof.

In the present invention, the glass particles preferably contain glass having a glass softening point of 600° C. or lower and a crystallization starting temperature of higher than 600° C., from the viewpoint of the oxidation resistance and the low resistivity of the electrode. Further, the glass softening point is measured by a general method using a ThermoMechanical Analyzer (TMA), and the crystallization starting temperature is measured by a general method using a ThermoGravimetry/Differential Thermal Analyzer (TG/DTA).

The glass particles generally included in the paste composition for an electrode may be constituted with lead-containing glass, at which silicon dioxide is efficiently captured. Examples of such the lead-containing glass include those described in Japanese Patent 03050064 and the like, which can be preferably used in the present invention.

Furthermore, in the present invention, in consideration of an effect on the environment, it is preferable to use lead-free glass which does not substantially contain lead. Examples of the lead-free glass include lead-free glass described in Paragraphs 0024 to 0025 of JP-A No. 2006-313744, and lead-free glass described in JP-A No. 2009-188281 and the like, and it is also preferable to appropriately select one from the lead-free glass as above for the present invention.

Moreover, the glass particles preferably include glass containing an oxide including phosphorous so as to efficiently capture silicon dioxide, and more preferably include glass including diphosphorus pentoxide (phosphoric acid glass, P₂O₅-based glass). Also, the glass particles preferably include glass which further includes divanadium pentoxide in addition to diphosphorus pentoxide (P₂O₅—V₂O₅-based glass). By further including divanadium pentoxide, the oxidation resistance is further improved, and the resistivity of the electrode is further reduced. It is thought that this is why, for example, further including divanadium pentoxide leads to a decrease in the softening point of glass.

When the glass particle includes diphosphorus pentoxide-divanadium pentoxide-based glass (P₂O₅—V₂O₅-based glass), the content of divanadium pentoxide is preferably 1% by mass or more based on the total mass of glass, and more preferably from 1 to 70% by mass.

Moreover, the diphosphorus pentoxide-divanadium pentoxide-based glass can further include other components, if necessary. Examples of other components include barium oxide (BaO), manganese dioxide (MnO₂), molybdenum oxide (MoO₃), antimony oxide (Sb₂O₃), sodium oxide (Na₂O), potassium oxide (K₂O), zirconium dioxide (ZrO₂), tungsten trioxide (WO₃), and tellurium oxide (TeO). By further including other components, silicon dioxide derived from the silicon nitride can be more efficiently captured. Further, the softening/melting temperature can be further reduced. In addition, the reaction of the copper-containing particles with silver particles that are added, if necessary, can be inhibited.

The content of the glass particles is preferably from 0.1 to 10% by mass, more preferably from 0.5 to 8% by mass, and even more preferably from 1 to 7% by mass, based on the total mass of the paste composition for an electrode. By including the glass particles at a content in this range, oxidation resistance, low resistivity of the electrode, and low contact resistance can be more effectively attained.

In the present invention, it is preferable to contain glass particles including P₂O₅—V₂O₅-based glass at an amount of from 0.1% by mass to 10% by mass as the glass particles, and it is more preferable to contain glass particles including P₂O₅—V₂O₅-based glass having a content of V₂O₅ of from 1% by mass or more at an amount of from 0.1 to 10% by mass.

### (Solvent and Resin)

The paste composition for an electrode of the first embodiment according to the present invention includes at least one kind of solvent and at least one kind of resin, thereby enabling adjustment of the liquid physical properties (for example, viscosity and surface tension) of the paste composition for an electrode of the present invention due to the application method selected when the paste composition is provided on the silicon substrate.

The solvent is not particularly limited. Examples thereof include hydrocarbon-based solvents such as hexane, cyclohexane, and toluene; chlorinated hydrocarbon-based solvents such as dichloroethylene, dichloroethane, and dichlorobenzene; cyclic ether-based solvents such as tetrahydrofuran, furan, tetrahydropyran, pyran, dioxane, 1,3-dioxolane, and trioxane; amide-based solvents such as N,N-dimethylformamide and N,N-dimethylacetamide; sulfoxide-based solvents such as dimethylsulfoxide, diethylsulfoxide; ketone-based solvents such as acetone, methyl ethyl ketone, diethyl ketone, and cyclohexanone; alcohol-based compounds such as ethanol, 2-propanol, 1-butanol, and diacetone alcohol; polyhydric alcohol ester-based solvents such as 2,2,4-trimethyl-1,3-pentanediol monoacetate, 2,2,4-trimethyl-1,3-pentanediol monopropiorate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate, and diethylene glycol monobutyl ether acetate; polyhydric alcohol ether-based solvents such as butyl cellosolve and diethylene glycol diethyl ether; terpene-based solvents such as α-terpinene, α-terpineol, myrcene, alloocimene, limonene, dipentene, α-pinene, β-pinene, terpineol, carvone, ocimene, and phellandrene, and mixtures thereof.

As the solvent in the present invention, from the viewpoint of applicability and printability when forming the paste composition for an electrode on a silicon substrate, at least one selected from polyhydric alcohol ester-based solvents, terpene-based solvents, and polyhydric alcohol ether-based solvents is preferred, and at least one selected from polyhydric alcohol ester-based solvents and terpene-based solvents is more preferred.

In the present invention, the solvents may be used singly or in a combination of two or more kinds thereof.

Furthermore, as the resin, the usual resin used in the related art can be used without any limitation as long as it is thermally decomposable by sintering. Specific examples thereof include cellulose-based resins such as methyl cellulose, ethyl cellulose, carboxymethyl cellulose, and nitrocellulose; polyvinyl alcohols; polyvinyl pyrrolidones; acryl resins; vinyl acetate-acrylic ester copolymers; butyral resins such as polyvinyl butyral; alkyd resins such as phenol-modified alkyd resins and castor oil fatty acid-modified alkyd resins; epoxy resins; phenol resins; and rosin ester resins.

As the resin in the present invention, from the viewpoint of the loss at a time of sintering, at least one selected from cellulose-based resins and acryl resins are preferred, and at least one selected from cellulose-based resins is more preferred.

In the present invention, the resins may be used singly or in combination of two or more kinds thereof.

In the paste composition for an electrode according to the present invention, the contents of the solvent and the resin can be appropriately selected due to desired liquid physical properties, and the kinds of the solvent and the resin to be used.

For example, the content of the resin is preferably from 0.01 to 5% by mass, more preferably from 0.05 to 4% by mass, even more preferably from 0.1 to 3% by mass, and still even more preferably from 0.15 to 2.5% by mass, based on the total mass of the paste composition for an electrode.

In addition, the total content of the solvent and the resin is preferably from 3 to 29.8% by mass, more preferably from 5 to 25% by mass, and even more preferably from 7 to 20% by mass, based on the total mass of the paste composition for an electrode.

By setting the contents of the solvent and the resin in the above-described ranges, the provision suitability becomes better when the paste composition for an electrode is provided on a silicon substrate, and thus, an electrode having a desired width and a desired height can be formed more easily.

### (Flux)

The paste composition for an electrode includes at least one kind of flux. By including the flux, the oxidation resistance is further improved, and the resistivity of the electrode to be formed is further reduced. Also, an effect that adhesion between the electrode material and the silicon substrate is improved can be attained.

The flux in the present invention is not particularly limited as long as it can inhibit the formation of an oxide film on the surface of the copper-containing particle. Specific preferable examples of the flux include fatty acids, boric acid compounds, fluoride compounds, and fluoroborate compounds.

More specific examples thereof include lauric acid, myristic acid, palmitic acid, stearic acid, sorbic acid, stearol acid, boron oxide, potassium borate, sodium borate, lithium borate, potassium fluoroborate, sodium fluoroborate, lithium fluoroborate, acidic potassium fluoride, acidic sodium fluoride, acidic lithium fluoride, potassium fluoride, sodium fluoride, and lithium fluoride.

Among those, from the viewpoint of heat resistance at a time of sintering the electrode material (a property that the flux is not volatilized at a low sintering temperature) and complement of the oxidation resistance of the copper-containing particles, particularly preferable examples of the flux include potassium borate and potassium fluoroborate.

In the present invention, these fluxes can be respectively used singly or in combination of two or more kinds thereof.

Furthermore, the content of the flux in the paste composition for an electrode according to the present invention is preferably from 0.1 to 5% by mass, more preferably from 0.3 to 4% by mass, even more preferably from 0.5 to 3.5% by mass, and particularly preferably from 0.7 to 3% by mass, based on the total mass of the paste composition for an electrode, from the viewpoint of effectively exhibiting the oxidation resistance of the copper-containing particles and from the viewpoint of reducing the porosity of a portion which is occurred by removal of the flux at a time of completion of the sintering of the electrode material.

### (Silver Particles)

The paste composition for an electrode according to the present invention preferably further includes at least one kind of silver particle. By including the silver particle, the oxidation resistance is further improved, and the resistivity as the electrode is further reduced. In addition, an effect that the solder connectivity is improved when forming a photovoltaic cell module can be obtained. This can be considered to be as follows, for example.

Generally, in a temperature region of from 600° C. to 900° C. that is an electrode-forming temperature region, a small amount of silver is solved into copper, and a small amount of copper is solved into silver, whereby a layer of the copper-silver solid solution (solid solution region) is formed at an interface between copper and silver. When a mixture of the copper-containing particles and the silver particles is heated at a high temperature, and then slowly cooled to room temperature, it is thought that the solid solution region is not generated. However, when forming an electrode, cooling is done for a few seconds from a high temperature region to a normal temperature, it is thought that the layer of the solid solution at a high temperature covers on the surface of the silver particles and the copper-containing particles as a non-equilibrium solid solution phase or as an eutectic structure of copper and silver. It can be thought that such a copper-silver solid solution layer contributes to the oxidation resistance of the copper-containing particle at an electrode-forming temperature.

The copper-silver solid solution layer starts to be formed at a temperature of from 300° C. to 500° C. or higher. Accordingly, it is thought that the oxidation resistance of the copper-containing particles can be improved more effectively by using the silver particles in combination with the copper-containing particles whose the peak temperature of the exothermic peak having a maximum area is 280° C. or higher by measured in the simultaneous ThermoGravimetry/Differential Thermal Analysis, whereby the resistivity of the electrode to be formed is further reduced.

Silver constituting the silver particles may contain other atoms which are inevitably incorporated. Examples of other atoms which are inevitably incorporated include Sb, Si, K, Na, Li, Ba, Sr, Ca, Mg, Be, Zn, Pb, Cd, Tl, V, Sn, Al, Zr, W, Mo, Ti, Co, Ni, and Au.

The particle diameter of the silver particle according to the present invention is not particularly limited, but it is preferably from 0.4 to 10 μm, and more preferably from 1 to 7 μm in terms of a particle diameter when the cumulative mass is 50% (“D50%). By setting the particle diameter to 0.4 μm or more, the oxidation resistance is improved more effectively. Further, by setting the particle diameter to 10 μm or less, the contact area at which the metal particles such as silver particles and copper-containing particle contact each other in the electrode increses, and thus, the resistivity is more effectively reduced.

In the paste composition for an electrode according to the present invention, the relationship between the particle diameter of the copper-containing particle (D50%) and the particle diameter of the silver particle (D50%) is not particularly limited, and it is preferable that the particle diameter (D50%) of one of the silver alloy particles and the silver particles is smaller than the particle diameter (D50%) of the other of the silver alloy particles and the silver particles, and it is more preferable that the ratio of the particle diameter of the one of the silver alloy particles and the silver particles with respect to the particle diameter of the other of the silver alloy particles and the silver particles be from 1 to 10. Consequently, the resistivity of the electrode is more effectively reduced. It is thought that this is caused from an increase in the contact area at which the metal particles such as copper-containing particles and silver particles contact each other in the electrode.

Moreover, the content of the silver particles in the paste composition for an electrode according to the present invention is preferably from 8.4 to 85.5% by mass, and more preferably from 8.9 to 80.1% by mass, based on the paste composition for an electrode, from the viewpoint of the oxidation resistance and the low resistivity of the electrode.

Furthermore, in the present invention, from the viewpoint of the oxidation resistance and the low resistivity of the electrode, the content of the copper-containing particles is preferably from 9 to 88% by mass, and more preferably from 17 to 77% by mass, when the total amount of the copper-containing particles and the silver particles are taken as 100% by mass. When the content of the copper-containing particles with respect to the silver particles is 9% by mass or more, for example, in a case in which the glass particles include divanadium pentoxide, a reaction between silver and vanadium is suppressed, which results in a reduction of the volume resistance of the electrode. Also, when a silicon substrate for forming an electrode is treated by an aqueous hydrofluoric acid solution for the purpose of improving the energy conversion efficiency of a photovoltaic cell, the above content of the silver alloy leads to improvement in the resistance of the electrode material against the aqueous hydrofluoric acid solution (this property means that the electrode material does not peel from the silicon substrate due to the aqueous hydrofluoric acid solution). Further, by setting the content of the copper-containing particles to 88% by mass or less, copper included in the copper-containing particles is further inhibited from being in contact with the silicon substrate, thereby further reducing the contact resistance of the electrode.

Moreover, in the paste composition for an electrode according to the present invention, the total content of the copper-containing particles and the silver particles is preferably from 70 to 94% by mass, more preferably from 72 to 92% by mass, and even more preferably from 74 to 88% by mass, from the viewpoint of the oxidation resistance, the low resistivity of the electrode, and the applicability on a silicon substrate.

By setting the total content of the copper-containing particles and the silver particles to 70% by mass or more, a suitable viscosity upon providing the paste composition for an electrode can be easily attained. Also, by setting the total content of the copper-containing particles and the silver particles to 94% by mass or less, the occurrence of abrasion upon providing the paste composition for an electrode can be inhibited more effectively.

Moreover, in the paste composition for an electrode according to the present invention, from the viewpoint of the oxidation resistance and the low resistivity of the electrode, it is preferable that the total content ratio of the copper-containing particles and the silver particles be from 70 to 94% by mass, the content of the glass particles be from 0.1 to 10% by mass, the total content of the solvent and the resin be from 3 to 29.8% by mass, and the content of the flux be from 0.1 to 5% by mass, and it is more preferable that the total content of the copper-containing particles and the silver particles be from 74 to 88% by mass, the content of the glass particles be from 1 to 7% by mass, the total content of the solvent and the resin be from 7 to 20% by mass, and the content of the flux be from 0.7 to 3% by mass.

### (Phosphorous-Containing Compound)

The paste composition for an electrode preferably further includes at least one kind of phosphorous-containing compound. Consequently, the oxidation resistance is improved more effectively, and the resistivity of the electrode is further reduced. Also, the elements in the phosphorous-containing compound are diffused into the silicon substrate as n-type dopant, and there can be obtained an effect that the power generation efficiency is improved in a photovoltaic cell made from it.

As the phosphorous-containing compound, from the viewpoint of the oxidation resistance and the low resistivity of the electrode, a compound having a high content of the phosphorous atoms in the molecule, which does not cause vaporization or decomposition under a temperature condition of approximately 200° C., is preferred.

Specific examples of the phosphorous-containing compound include phosphorous-based inorganic acids such as phosphoric acid, phosphates such as ammonium phosphate, phosphoric esters such as alkyl phosphate ester and aryl phosphate ester, cyclic phosphazenes such as hexaphenoxy phosphazene, and derivatives thereof.

The phosphorous-containing compound in the present invention is preferably at least one selected from the group consisting of phosphoric acid, ammonium phosphate, phosphoric ester, and cyclic phosphazene, and more preferably at least one selected from the group consisting of phosphoric ester and cyclic phosphazene, from the viewpoint of the oxidation resistance and the low resistivity of the electrode.

The content of the phosphorous-containing compound in the present invention is preferably from 0.5 to 10% by mass, and more preferably from 1 to 7% by mass, based on the total mass of the paste composition for an electrode, from the viewpoint of the oxidation resistance and the low resistivity of the electrode.

Furthermore, in the present invention, it is preferable that at least one selected from the group consisting of phosphoric acid, ammonium phosphate, phosphoric ester, and cyclic phosphazene be included in an amount of from 0.5 to 10% by mass based on the total mass of the paste composition for an electrode as the phosphorous-containing compound, and it is more preferable that at least one selected from the group consisting of phosphoric ester and cyclic phosphazene be included in an amount of from 1 to 7% by mass based on the total mass of the paste composition for an electrode.

Moreover, when the paste composition for an electrode according to the present invention includes the phosphorous-containing compound, from the viewpoint of the oxidation resistance and the low resistivity of the electrode, it is preferable that the total content of the copper-containing particles and the silver particles be from 70 to 94% by mass, the content of the glass particles be from 0.1 to 10% by mass, the total content of the solvent, the resin, and the phosphorous-containing compound be from 5 to 20% by mass, and the content of the flux be from 0.1 to 5% by mass. It is more preferable that the total content of the copper-containing particles and the silver particles be from 74 to 88% by mass, the content of the glass particles be from 1 to 7% by mass, the total content of the solvent, the resin, and the phosphorous-containing compound be from 1 to 7% by mass, and the content of the flux be from 0.7 to 3% by mass.

### (Other Components)

Furthermore, the paste composition for an electrode according to the present invention may include, in addition to the above-described components, other components generally used in the related art, if necessary. Examples of other components include a plasticizer, a dispersant, a surfactant, an inorganic binder, a metal oxide, a ceramic, and an organic metal compound.

The method for preparing the paste composition for an electrode according to the present invention is not particularly limited. The paste composition for an electrode according to the present invention can be prepared by dispersing and mixing copper-containing particles, glass particles, a solvent, a resin, silver particles to be added, if necessary, and the like, using a typically used dispersing/mixing method.

### (Method for Producing Electrode Using Paste Composition for Electrode)

As for the method for preparing an electrode using the paste composition for an electrode according to the present invention, the paste composition for an electrode can be provided in a region in which the electrode is formed, dried, and then sintered to form the electrode in a desired region. By using the paste composition for an electrode, an electrode having a low resistivity can be formed even with a sintering treatment in the presence of oxygen (for example, in the atmosphere).

Specifically, for example, when an electrode for a photovoltaic cell is formed using the paste composition for an electrode, the paste composition for an electrode can be provided to a silicon substrate to a desired shape, dried, and then sintered to form an electrode for a photovoltaic cell having a low resistivity in a desired shape. Further, by using the paste composition for an electrode, an electrode having a low resistivity can be formed even with a sintering treatment in the presence of oxygen (for example, in the atmosphere).

Examples of the method for applying the paste composition for an electrode on a silicon substrate include screen printing, an ink-jet method, and a dispenser method, but from the viewpoint of the productivity, application by screen printing is preferred.

When the paste composition for an electrode according to the present invention is applied by screen printing, it is preferable that the viscosity be in the range of from 80 to 1000 Pa·s. The viscosity of the paste composition for an electrode is measured using a Brookfield HBT viscometer at 25° C.

The amount of the paste composition for an electrode to be provided can be appropriately selected according to the size of the electrode formed. For example, the amount of the paste composition for an electrode to be provided can be from 2 to 10 g/m², and preferably from 4 to 8 g/m².

Moreover, as a heat treatment condition (sintering condition) when forming an electrode using the paste composition for an electrode according to the present invention, heat treatment conditions generally used in the related art can be adopted.

Generally, the heat treatment temperature (sintering temperature) is from 800 to 900° C. On the other hand, when using the paste composition for an electrode according to the present invention, a heat treatment condition at a lower temperature can be adopted, and an electrode having good characteristics can be formed at a heat treatment temperature of, for example, from 600 to 850° C.

In addition, the heat treatment time can be appropriately selected depending on the heat treatment temperatures, and it may be, for example, from 1 second to 20 seconds.

### <Photovoltaic Cell>

The photovoltaic cell of the present invention has an electrode formed by sintering the paste composition for an electrode provided on the silicon substrate in the presence of oxygen. As a result, a photovoltaic cell having good characteristics can be obtained, and the productivity of the photovoltaic cell is excellent.

Hereinbelow, specific examples of the photovoltaic cell of the present invention will be described with reference to the drawings, but the present invention is not limited thereto.

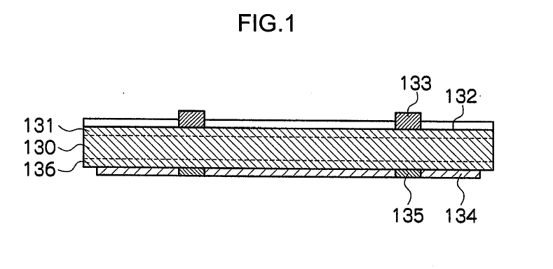

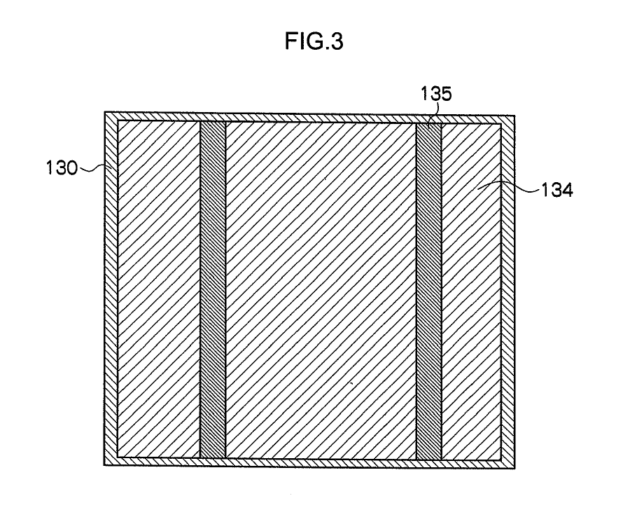

A cross-sectional view, and schematic views of the light-receiving surface and the back surface of one example of the representative photovoltaic cell elements are shown in FIGS. 1, 2 and 3, respectively.

Typically, monocrystalline or polycrystalline Si, or the like is used for a semiconductor substrate 130 of a photovoltaic cell element. This semiconductor substrate 130 contains boron and the like to constitute a p-type semiconductor. Unevenness (texture, not shown) is formed on the light-receiving surface side by etching so as to inhibit the reflection of sunlight. Phosphorous and the like are doped on the light-receiving surface side to provide a diffusion layer 131 of an n-type semiconductor with a thickness on the order of submicrons, and a p/n junction is formed at the boundary with the p-type bulk portion. Also, on the light-receiving surface side, an anti-reflection layer 132 such as silicon nitride with a film thickness of around 100 nm is provided on the diffusion layer 131 by a vapor deposition method.

Next, a light-receiving surface electrode 133 provided at the light-receiving surface side, a current collection electrode 134 formed at the back surface, and an output extraction electrode 135 will be described. The light-receiving surface electrode 133 and the output extraction electrode 135 are formed from the paste composition for an electrode. Further, the current collection electrode 134 is formed from the aluminum electrode paste composition including glass powders. These electrodes are formed by applying the paste composition for a desired pattern by screen printing or the like, drying, and then sintering at about 600 to 850° C. in an atmosphere.

Here, on the light-receiving surface side, the glass particles included in the paste composition for an electrode to form the light-receiving surface electrode 133 undergo a reaction with the anti-reflection layer 132 (fire-through), thereby electrically connecting (ohmic contact) the light-receiving surface electrode 133 and the diffusion layer 131.

In the present invention, due to using the paste composition for an electrode to form the light-receiving surface electrode 133 including copper as a conductive material, the oxidation of copper is inhibited, whereby the light-receiving surface electrode 133 having a low resistivity is produced at high productivity.

Further, on the back surface side, upon sintering, aluminum which is included in the aluminum electrode paste composition for forming the current collection electrode 134 is diffused on and into the back surface of the semiconductor substrate 130 to form an electrode component diffusion layer 136, and as a result, ohmic contact is formed among the semiconductor substrate 130, the current collection electrode 134, and the output extraction electrode 135.

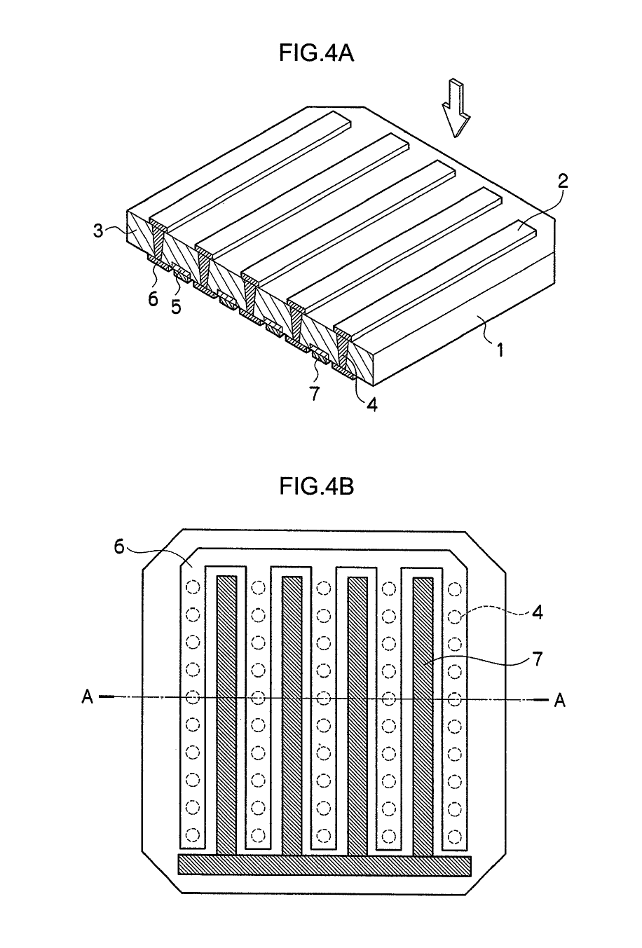

In FIG. 4, the perspective view (a) of the light-receiving surface and the AA cross-section structure, and the plane view (b) of the back surface side electrode structure in one example of the photovoltaic cell element are shown as another embodiment according to the present invention.

As shown in FIG. 4, in a cell wafer 1 consisting of a silicon substrate of a p-type semiconductor, a through-hole which passes through both sides of the light-receiving surface side and the back surface side is formed by laser drilling, etching, or the like. Further, a texture (not shown) for improving the efficiency of incident light is formed on the light-receiving surface side. Also, the light-receiving surface side has an n-type semiconductor layer 3 formed by n-type diffusion treatment, and an anti-reflection film (not shown) formed on the n-type semiconductor layer 3. These are prepared by the same processes as for a conventional crystal Si-type photovoltaic cell.

Next, the paste composition for an electrode of the present invention is filled in the inside of the through-hole previously formed by a printing method or an ink-jet method, and also, the paste composition for an electrode of the present invention is similarly printed in the grid shape on the light-receiving surface side, thereby forming a composition layer which forms the through-hole electrode 4 and the grid electrode 2 for current collection.

Here, regarding the paste used for filling and printing, although it is preferable to use the most suitable paste for each process from the point of view of properties such as viscosity, one paste of the same composition may be used for filling and printing at the same time.

On the other hand, a high-concentration doped layer 5 is formed on the opposite side of the light-receiving surface (back surface side) so as to prevent the carrier recombination. Here, as an impurity element for forming the high-concentration doped layer 5, boron (B) or aluminum (Al) is used, and a p⁺ layer is formed. This high-concentration doped layer 5 may be formed by carrying out a thermal diffusion treatment using, for example, B as a diffusion source in the process of preparing a cell before forming the anti-reflection film, or when using Al, it may also be formed by printing an Al paste on the opposite surface side in the printing step.

Thereafter, the paste composition for an electrode is printed on the side of an anti-reflection film and is also filled in the inside of the through-hole, which is formed on the light-receiving surface side, and then is sintered at 650 to 850° C., whereby the paste composition can attain ohmic contact with the n-type layer as an under layer by a fire-through effect.

Furthermore, as shown in the plane view of FIG. 4(b), the paste composition for an electrode according to the present invention is printed in stripe shapes on each of the n side and the p side, and sintered, and thus, the back surface electrodes 6 and 7 are formed on the opposite surface side.

In the present invention, the through-hole electrode 4, the grid electrode 2 for current collection, the back surface electrode 6, and the back surface electrode 7 are formed using the paste composition for an electrode. As a result, despite including copper as a conductive metal, the oxidation of copper is inhibited, whereby the through-hole electrode 4 having a low resistivity, and the grid electrode 2 for current collection, the back surface electrode 6 and the back surface electrode 7 are formed with high productivity.

Moreover, the paste composition for an electrode of the present invention is not restricted to the applications of photovoltaic cell electrodes described above, and can also be appropriately used in applications such as, for example, electrode wirings and shield wirings of plasma displays, ceramic condensers, antenna circuits, various sensor circuits, and heat dissipation materials of semiconductor devices.

### EXAMPLES

Hereinafter, the present invention will be described in detail with reference to Examples, but the present invention is not limited to these Examples. Further, unless otherwise specified, “parts” and “%” are based on mass.

### Example 1A

### (a) Preparation of Paste Composition for Electrode

A phosphorous-containing copper alloy including 1% by mass of phosphorous is prepared, dissolved, made into powder by a water atomization method, then dried and classified. The classified powders were blended and subjected to deoxidation/dehydration treatments to prepare phosphorous-containing copper alloy particles including 1% by mass of phosphorous. Further, the particle diameter of the phosphorous-containing copper alloy particle (D50%) was 1.5 μm.

A glass including 32 parts of vanadium oxide (V₂O₅), 26 parts of phosphorous oxide (P₂O₅), 10 parts of barium oxide (BaO), 10 parts of tungsten oxide (WO₃), 1 part of sodium oxide (Na₂O), 3 parts of potassium oxide (K₂O), 10 parts of zinc oxide (ZnO), and 8 parts of manganese oxide (ZnO) (hereinafter abbreviated as “G19” in some cases) was prepared. The glass G19 obtained had a softening point of 447° C. and a crystallization temperature of 600° C. or higher.

By using the glass G19 obtained, glass particles having a particle diameter (D50%) of 1.7 μm were obtained.

39.2 parts of the phosphorous-containing copper alloy particles obtained above, 45.9 parts of silver particles (particle diameter (D50%) 3 μm, high-purity chemical product manufactured by Sigma-Aldrich Corporation), 1.7 parts of glass particles, 1 part of potassium fluoroborate as a flux, and 13.2 parts of a butyl carbitol acetate (BCA) solution including 4% of ethyl cellulose (EC) were mixed and stirred in a mortar made of agate for 20 minutes under mixing, thereby preparing a paste composition 1A for an electrode.

### (b) Production of Photovoltaic Cell

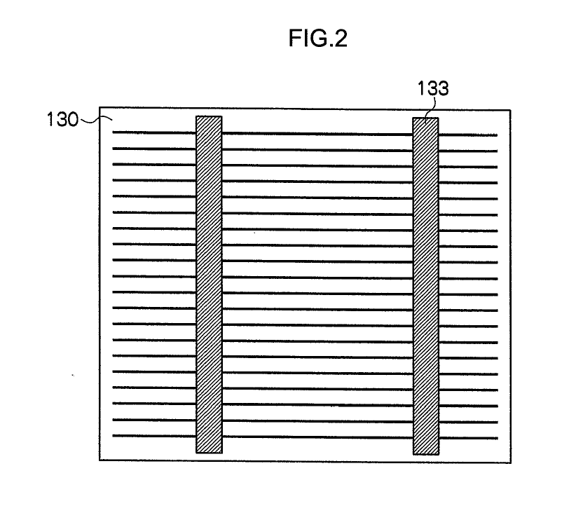

A p-type semiconductor substrate having a film thickness of 190 μm, in which an n-type semiconductor layer, a texture, and an anti-reflection film (silicon nitride film) were formed on the light-receiving surface, was prepared, and cut to a size of 125 mm×125 mm. The paste composition 1A for an electrode obtained above was printed on the light-receiving surface for an electrode pattern as shown in FIG. 2, using a screen printing method. The pattern of the electrode was constituted with finger lines with a 150 μm width and bus bars with a 1.1 mm width, and the printing conditions (a mesh of a screen plate, a printing speed, a printing pressure) were appropriately adjusted so as to give a film thickness after sintering of 20 μm. The resultant was put into an oven heated at 150° C. for 15 minutes, and the solvent was removed by vaporization.

Subsequently, an aluminum electrode paste was similarly printed on the entire surface of the back surface by screen printing. The printing conditions were appropriately adjusted so as to give a film thickness after sintering of 40 μm. The resultant was put into an oven heated at 150° C. for 15 minutes, and the solvent was removed by vaporization.

Then, a heating treatment (sintering) was carried out at 850° C. for 2 seconds under an air atmosphere in an infrared rapid heating furnace, and a photovoltaic cell 1A having a desired electrode formed therein was prepared.

### Example 2A

In the same manner as in Example 1A, except that the temperature of the heating treatment (sintering) upon forming an electrode was changed from 850° C. to 750° C. for 10 seconds in Example 1A, a photovoltaic cell 2A having a desired electrode formed therein was prepared.

### Example 3A

In the same manner as in Example 1A, except that 1 part of phosphoric acid was further added, and the particle diameter (D50%) of the silver particle was changed to 1 μm in Example 1A, a photovoltaic cell 3A having a desired electrode formed therein was prepared.

### Example 4A

In the same manner as in Example 1A, except that the addition amount of potassium fluoroborate as a flux was changed from 1 part to 2 parts, and the addition amount of the butyl carbitol acetate (BCA) solution including 4% of ethyl cellulose (EC) was changed to 10.2 parts in Example 1A, a photovoltaic cell 4A having a desired electrode formed therein was prepared.

### Examples 5A, 7A, and 8A

In the same manner as in Example 1A, except that the fluxes shown in Table 1 were used instead in Example 1A, photovoltaic cells 5A, 7A, and 8A each having a desired electrode formed therein, were prepared.

### Example 6A

In the same manner as in Example 5A, except that the glass particles (AY1) prepared as below were used instead of the glass particles (G19) in Example 1A, a photovoltaic cell 6A having a desired electrode formed therein was prepared.

The glass particles (AY1) included 45 parts of vanadium oxide (V₂O₅), 24.2 parts of phosphorous oxide (P₂O₅), 20.8 parts of barium oxide (BaO), 5 parts of antimony oxide (Sb₂O₃), and 5 parts of tungsten oxide (WO₃), and had a particle diameter (D50%) of 1.7 μm. Further, the glass had a softening point of 492° C. and a crystallization temperature of 600° C. or higher.

### Comparative Example 1A

In the same manner as in Example 1A, except that the flux was not added in the preparation of the paste composition for an electrode in Example 1A, a comparative photovoltaic cell 1A having a desired electrode formed therein was prepared.

TABLE 1

| | Copper-containing particles | | | Silver particles | | | | 4% EC- | | | | |
|---|---|---|---|---|---|---|---|---|---|---|---|---|
| | | | Particle | | Particle | | | containing | | | Phosphorous | Treatment |
| | | | diameter | | diameter | Glass particles | | BCA | Flux | | compound | temperature/ |
| | | Content | (D50%) | Content | (D50%) | Content | | solution | Content | | Content | Treatment |
| Example | Type | (parts) | (μm) | (parts) | (μm) | (parts) | Type | (parts) | (parts) | Type | (parts) | time |
| Example | P | 39.2 | 1.5 | 45.9 | 3 | 1.7 | G19 | 13.2 | 1 | Potassium | 0 | 850° C./ |
| 1A | contained | | | | | | | | | fluoroborate | | 2 seconds |
| Example | P | 39.2 | 1.5 | 45.9 | 3 | 1.7 | G19 | 13.2 | 1 | Potassium | 0 | 750° C./ |
| 2A | contained | | | | | | | | | fluoroborate | | 10 seconds |
| Example | P | 39.2 | 1.5 | 45.9 | 1 | 1.7 | G19 | 13.2 | 1 | Potassium | 1 | 850° C./ |
| 3A | contained | | | | | | | | | fluoroborate | | 2 seconds |
| Example | P | 39.2 | 1.5 | 45.9 | 3 | 1.7 | G19 | 10.2 | 2 | Potassium | 0 | 850° C./ |
| 4A | contained | | | | | | | | | fluoroborate | | 2 seconds |
| Example | P | 39.2 | 1.5 | 45.9 | 3 | 1.7 | G19 | 13.2 | 1 | Lauric acid | 0 | 850° C./ |
| 5A | contained | | | | | | | | | | | 2 seconds |
| Example | P | 39.2 | 1.5 | 45.9 | 3 | 1.7 | AY1 | 13.2 | 1 | Lauric acid | 0 | 850° C./ |
| 6A | contained | | | | | | | | | | | 2 seconds |
| Example | P | 39.2 | 1.5 | 45.9 | 3 | 1.7 | G19 | 13.2 | 1 | Sodium | 0 | 850° C./ |
| 7A | contained | | | | | | | | | fluoroborate | | 2 seconds |
| Example | P | 39.2 | 1.5 | 45.9 | 3 | 1.7 | G19 | 13.2 | 1 | Potassium | 0 | 850° C./ |
| 8A | contained | | | | | | | | | borate | | 2 seconds |
| Comp. | P | 39.2 | 1.5 | 85.1 | 3 | 1.7 | G19 | 13.2 | 0 | — | 0 | 850° C./ |
| Example | contained | | | | | | | | | | | 2 seconds |
| 1A | | | | | | | | | | | | |

### <Evaluation>

The photovoltaic cells prepared were evaluated with a combination of WXS-155 S-10 manufactured by Wacom-Electric Co., Ltd. as artificial sunlight and a measurement device of I-V CURVE TRACER MP-160 (manufactured by EKO INSTRUMENT CO., LTD.) as a current-voltage (I-V) evaluation and measurement device. Each of the values measured for the power generation performances as a photovoltaic cell are shown in Table 2 in terms of a relative value when the value measured in Comparative Example 1A was taken as 100.0. Further, Eff (conversion efficiency), FF (fill factor), Voc (open voltage), and Jsc (short circuit current) indicating the power generation performances as a photovoltaic cell were obtained by carrying out the measurement method in accordance with each of JIS-C-8912, JIS-C-8913, and JIS-C-8914.

TABLE 2

| | Power generation performance as photovoltaic cell | | | |
|---|---|---|---|---|
| | Eff | FF | Voc | Jsc |
| | (relative value) | (relative | (relative | (relative value) |
| | Conversion | value) | value) | Short circuit |
| Example | efficiency | Fill factor | Open voltage | current |
| Example 1A | 102.5 | 103.0 | 99.3 | 101.3 |
| Example 2A | 84.4 | 92.0 | 91.1 | 93.2 |
| Example 3A | 104.2 | 103.3 | 99.6 | 103.2 |
| Example 4A | 101.1 | 102.0 | 98.9 | 100.0 |
| Example 5A | 99.8 | 100.5 | 97.8 | 100.2 |
| Example 6A | 99.2 | 100.2 | 98.1 | 99.8 |
| Example 7A | 103.5 | 101.2 | 98.4 | 102.3 |
| Example 8A | 102.4 | 100.5 | 98.2 | 101.2 |
| Comparative | 100.0 | 100.0 | 100.0 | 100.0 |
| Example 1A | | | | |

### Example 1B

In the same manner as in Example 1A, except that the silver-coated copper particles prepared from the silver-coated copper particles (manufactured by the present company, silver-coating amount 20% by mass, particle diameter 5.8 μm) that had been prepared by a method described in JP-A No. 14-100191 was used instead of the phosphorous-containing copper alloy in Example 1A, a photovoltaic cell 1B having a desired electrode formed therein was prepared.

### Example 2B

In the same manner as in Example 1B, except that the temperature of the heating treatment (sintering) upon forming an electrode was changed from 850° C. to 750° C. for 10 seconds in Example 1B, a photovoltaic cell 2B having a desired electrode formed therein was prepared.

### Example 3B

In the same manner as in Example 1B, except that 1 part of phosphoric acid was further added, and the particle diameter (D50%) of the silver particle was changed to 1 μm in Example 1B, a photovoltaic cell 3B having a desired electrode formed therein was prepared.

### Example 4B

In the same manner as in Example 1B, except that the addition amount of potassium fluoroborate as a flux was changed from 1 part to 2 parts, and the addition amount of the butyl carbitol acetate (BCA) solution including 4% of ethyl cellulose (EC) was changed to 10.2 parts in Example 1B, a photovoltaic cell 4B having a desired electrode formed therein was prepared.

### Examples 5B and 7B

In the same manner as in Example 1B, except that the fluxes shown in Table 3 were used instead in Example 1B, photovoltaic cells 5B and 7B, each having a desired electrode formed therein, were prepared.

### Example 6B

In the same manner as in Example 5B, except that the glass particles (AY1) prepared as below were used instead of the glass particles (G19) in Example 1B, a photovoltaic cell 6B having a desired electrode formed therein was prepared.

### Comparative Example 1B

In the same manner as in Example 1B, except that the flux was not used in the preparation of the paste composition for an electrode in Example 1B, a comparative photovoltaic cell 1B having a desired electrode formed therein was prepared.

TABLE 3

| | Copper-containing particles | | | Silver particles | | | | 4% EC- | | | | |
|---|---|---|---|---|---|---|---|---|---|---|---|---|
| | | | Particle | | Particle | | | containing | | | Phosphorous | Treatment |
| | | | diameter | | diameter | Glass particles | | BCA | Flux | | compound | temperature/ |
| | | Content | (D50%) | Content | (D50%) | Content | | solution | Content | | Content | Treatment |
| Example | Type | (parts) | (μm) | (parts) | (μm) | (parts) | Type | (parts) | (parts) | Type | (parts) | time |
| Example 1B | Ag | 39.2 | 5.8 | 45.9 | 3 | 1.7 | G19 | 13.2 | 1 | Potassium | 0 | 850° C./ |
| | coated | | | | | | | | | fluoroborate | | 2 seconds |
| Example 2B | Ag | 39.2 | 5.8 | 45.9 | 3 | 1.7 | G19 | 13.2 | 1 | Potassium | 0 | 750° C./ |
| | coated | | | | | | | | | fluoroborate | | 10 seconds |
| Example 3B | Ag | 39.2 | 5.8 | 45.9 | 1 | 1.7 | G19 | 13.2 | 1 | Potassium | 1 | 850° C./ |
| | coated | | | | | | | | | fluoroborate | | 2 seconds |
| Example 4B | Ag | 39.2 | 5.8 | 45.9 | 3 | 1.7 | G19 | 10.2 | 2 | Potassium | 0 | 850° C./ |
| | coated | | | | | | | | | fluoroborate | | 2 seconds |
| Example 5B | Ag | 39.2 | 5.8 | 45.9 | 3 | 1.7 | G19 | 13.2 | 1 | Lauric acid | 0 | 850° C./ |
| | coated | | | | | | | | | | | 2 seconds |
| Example 6B | Ag | 39.2 | 5.8 | 45.9 | 3 | 1.7 | G19 | 13.2 | 1 | Lauric acid | 0 | 850° C./ |
| | coated | | | | | | | | | | | 2 seconds |
| Example 7B | Ag | 39.2 | 5.8 | 45.9 | 3 | 1.7 | AY1 | 13.2 | 1 | Sodium | 0 | 850° C./ |
| | coated | | | | | | | | | fluoroborate | | 2 seconds |
| Comparative | Ag | — | 5.8 | 85.1 | 3 | 1.7 | G19 | 13.2 | 0 | — | 0 | 850° C./ |
| Example 1B | coated | | | | | | | | | | | 2 seconds |

### <Evaluation>

The cells of the photovoltaic cells prepared were evaluated with a combination of WXS-155 S-10 manufactured by Wacom-Electric Co., Ltd. as artificial sunlight and a measurement device of I-V CURVE TRACER MP-160 (manufactured by EKO INSTRUMENT CO., LTD.) as a current-voltage (I-V) evaluation and measurement device. Each of the values measured for the power generation performances as a photovoltaic cell are shown in Table 4 in terms of a relative value when the value measured in Comparative Example 1B was taken as 100.0. Further, Eff (conversion efficiency), FF (fill factor), Voc (open voltage), and Jsc (short circuit current) indicating the power generation performances as a photovoltaic cell were obtained by carrying out the measurement method in accordance with each of JIS-C-8912, JIS-C-8913, and JIS-C-8914.

TABLE 4

| | Power generation performance as photovoltaic cell | | | |
|---|---|---|---|---|
| | Eff | FF | Voc | Jsc |
| | (relative value) | (relative | (relative | (relative value) |
| | Conversion | value) | value) | Short circuit |
| Example | efficiency | Fill factor | Open voltage | current |
| Example 1B | 102.3 | 101.2 | 98.6 | 100.3 |
| Example 2B | 85.6 | 93.3 | 94.0 | 92.1 |
| Example 3B | 105.2 | 104.2 | 99.4 | 101.2 |
| Example 4B | 100.2 | 101.1 | 98.6 | 100.6 |
| Example 5B | 101.1 | 100.9 | 98.4 | 100.3 |
| Example 6B | 101.2 | 100.7 | 98.2 | 100.5 |
| Example 7B | 104.3 | 103.9 | 99.5 | 103.7 |
| Comparative | 100.0 | 100.0 | 100.0 | 100.0 |
| Example 1B | | | | |

### Example 1C

In the same manner as in Example 1A, except that the surface-treated copper particles prepared as below were used instead of the phosphorous-containing copper alloy in Example 1A, a photovoltaic cell 1C having a desired electrode formed therein was prepared.

As a surface treatment agent, a 50% surface treatment solution was prepared by dissolving benzotriazole (BTA) in ethanol as a solvent. Copper powders (manufactured by Fukuda Metal Foil & Powder Co., Ltd.), purity 99.9%, particle diameter 5 μm) were immersed therein for 50 minutes, and then dried to prepare surface-treated copper particles. The content of the surface treatment agent in the surface-treated copper particles was 1% based on the total mass of the surface-treated copper particles. Further, the particle diameter (D50%) was 5 μm.

### Example 2C

In the same manner as in Example 1C, except that the temperature of the heating treatment (sintering) when forming an electrode was changed from 850° C. to 750° C. for 10 seconds in Example 1C, a photovoltaic cell 2C having a desired electrode formed therein was prepared.

### Example 3C

In the same manner as in Example 1C, except that 1 part of phosphoric acid was further added, and the particle diameter (D50%) of the silver particle was changed to 1 μm in Example 1C, a photovoltaic cell 3C having a desired electrode formed therein was prepared.

### Example 4C

In the same manner as in Example 1C, except that the addition amount of potassium fluoroborate as a flux was changed from 1 part to 2 parts, and the addition amount of the butyl carbitol acetate (BCA) solution including 4% of ethyl cellulose (EC) was changed to 10.2 parts in Example 1C, a photovoltaic cell 4C having a desired electrode formed therein was prepared.

### Examples 5C and 7C

In the same manner as in Example 1C, except that the flux shown in Table 5 was used instead in Example 1C, photovoltaic cells 5C and 7C, each having a desired electrode formed therein, were prepared.

### Example 6C

In the same manner as in Example 5C, except that the glass particles (AY1) were used instead of the glass particles (G19) in Example 1C, a photovoltaic cell 6C having a desired electrode formed therein was prepared.

### Comparative Example 1C

In the same manner as in Example 1C, except that the flux was not used in the preparation of the paste composition for an electrode in Example 1C, a comparative photovoltaic cell 1C having a desired electrode formed therein was prepared.

TABLE 5

| | Copper-containing articles | | | Silver particles | | | | 4% EC- | | | | |
|---|---|---|---|---|---|---|---|---|---|---|---|---|
| | | | Particle | | Particle | | | containing | | | Phosphorous | Treatment |
| | | | diameter | | diameter | Glass particles | | BCA | Flux | | compound | temperature/ |
| | | Cont. | (D50%) | Cont. | (D50%) | Cont. | | solution | Cont. | | Cont. | Treatment |
| Example | Type | (parts) | (μm) | (parts) | (μm) | (parts) | Type | (parts) | (parts) | Type | (parts) | time |
| Example | Surface | 39.2 | 5 | 45.9 | 3 | 1.7 | G19 | 13.2 | 1 | Potassium | 0 | 850° C./ |
| 1C | treated | | | | | | | | | fluoroborate | | 2 seconds |
| Example | Surface | 39.2 | 5 | 45.9 | 3 | 1.7 | G19 | 13.2 | 1 | Potassium | 0 | 750° C./ |
| 2C | treated | | | | | | | | | fluoroborate | | 10 seconds |
| Example | Surface | 39.2 | 5 | 45.9 | 1 | 1.7 | G19 | 13.2 | 1 | Potassium | 1 | 850° C./ |
| 3C | treated | | | | | | | | | fluoroborate | | 2 seconds |
| Example | Surface | 39.2 | 5 | 45.9 | 3 | 1.7 | G19 | 10.2 | 2 | Potassium | 0 | 850° C./ |
| 4C | treated | | | | | | | | | fluoroborate | | 2 seconds |
| Example | Surface | 39.2 | 5 | 45.9 | 3 | 1.7 | G19 | 13.2 | 1 | Lauric acid | 0 | 850° C./ |
| 5C | treated | | | | | | | | | | | 2 seconds |
| Example | Surface | 39.2 | 5 | 45.9 | 3 | 1.7 | AY1 | 13.2 | 1 | Lauric acid | 0 | 850° C./ |
| 6C | treated | | | | | | | | | | | 2 seconds |
| Example | Surface | 39.2 | 5 | 45.9 | 3 | 1.7 | G19 | 13.2 | 1 | Sodium | 0 | 850° C./ |
| 7C | treated | | | | | | | | | fluoroborate | | 2 seconds |
| Comp. | Surface | — | 5 | 85.1 | 3 | 1.7 | G19 | 13.2 | 0 | — | 0 | 850° C./ |
| Example | treated | | | | | | | | | | | 2 seconds |
| 1C | | | | | | | | | | | | |

### <Evaluation>

The cells of the photovoltaic cells prepared were evaluated with a combination of WXS-155 S-10 manufactured by Wacom-Electric Co., Ltd. as artificial sunlight and a measurement device of I-V CURVE TRACER MP-160 (manufactured by EKO INSTRUMENT CO., LTD.) as a current-voltage (I-V) evaluation and measurement device. Each of the values measured for the power generation performances as a photovoltaic cell are shown in Table 6 in terms of a relative value when the value measured in Comparative Example 1C was taken as 100.0. Further, Eff (conversion efficiency), FF (fill factor), Voc (open voltage), and Jsc (short circuit current) indicating the power generation performances as a photovoltaic cell were obtained by carrying out the measurement method in accordance with each of JIS-C-8912, JIS-C-8913, and JIS-C-8914.

TABLE 6

| | Power generation performance as photovoltaic cell | | | |
|---|---|---|---|---|
| | Eff | FF | Voc | Jsc |
| | (relative value) | (relative | (relative | (relative value) |
| | Conversion | value) | value) | Short circuit |
| Example | efficiency | Fill factor | Open voltage | current |
| Example 1C | 101.2 | 100.2 | 97.6 | 100.2 |
| Example 2C | 84.6 | 92.2 | 93.3 | 91.1 |
| Example 3C | 102.3 | 101.2 | 98.8 | 101.3 |
| Example 4C | 100.3 | 100.0 | 99.5 | 101.3 |
| Example 5C | 100.1 | 99.9 | 98.8 | 100.2 |
| Example 6C | 101.8 | 99.3 | 98.5 | 101.3 |
| Example 7C | 103.5 | 102.7 | 99.6 | 102.5 |
| Comparative | 100.0 | 100.0 | 100.0 | 100.0 |
| Example 1C | | | | |

The foregoing description of the embodiments of the present invention has been provided for the purposes of illustration and description. It is not intended to be exhaustive or to limit the present invention to the precise forms disclosed. Obviously, many modifications and variations will be apparent to practitioners skilled in the art. The embodiments were chosen and described in order to best explain the principles of the present invention and its practical applications, thereby enabling others skilled in the art to understand the present invention for various embodiments and with the various modifications as are suited to the particular use contemplated. It is intended that the scope of the present invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

1. A paste composition for an electrode, the paste composition comprising:
metal particles including copper as a main component;
a flux;
glass particles;
a solvent; and
a resin.

2. The paste composition for an electrode according to claim 1, further comprising silver particles.

3. The paste composition for an electrode according to claim 1, wherein the metal particles including copper as a main component are at least one selected from:
phosphorous-containing copper alloy particles;
silver-coated copper particles; or
copper particles, the copper particles being surface-treated with at least one selected from the group consisting of triazole compounds, saturated fatty acids, unsaturated fatty acids, inorganic metal compound salts, organic metal compound salts, polyaniline-based resins and metal alkoxides.

4. The paste composition for an electrode according to claim 1, wherein the flux is at least one selected from fatty acids, boric acid compounds, fluoride compounds, or fluoroborate compounds.

5. The paste composition for an electrode according to claim 1, wherein the glass particles include an oxide comprising phosphorous.

6. A photovoltaic cell having an electrode, wherein the electrode is formed by sintering the paste composition for an electrode according to claim 1 which is applied to a silicon substrate.

7. The paste composition for an electrode according to claim 2, wherein the metal particles including copper as a main component are at least one selected from:
phosphorous-containing copper alloy particles;
silver-coated copper particles; or
copper particles, the copper particles being surface-treated with at least one selected from the group consisting of triazole compounds, saturated fatty acids, unsaturated fatty acids, inorganic metal compound salts, organic metal compound salts, polyaniline-based resins and metal alkoxide.

8. The paste composition for an electrode according to claim 7, wherein the flux is at least one selected from fatty acids, boric acid compounds, fluoride compounds, or fluoroborate compounds.

9. The paste composition for an electrode according to claim 2, wherein the flux is at least one selected from fatty acids, boric acid compounds, fluoride compounds, or fluoroborate compounds.

10. The paste composition for an electrode according to claim 3, wherein the flux is at least one selected from fatty acids, boric acid compounds, fluoride compounds, or fluoroborate compounds.

11. The paste composition for an electrode according to claim 2, wherein the glass particles include an oxide comprising phosphorous.

12. The paste composition for an electrode according to claim 3, wherein the glass particles include an oxide comprising phosphorous.

13. The paste composition for an electrode according to claim 4, wherein the glass particles include an oxide comprising phosphorous.

14. The paste composition for an electrode according to claim 7, wherein the glass particles include an oxide comprising phosphorous.

15. The paste composition for an electrode according to claim 8, wherein the glass particles include an oxide comprising phosphorous.

16. The paste composition for an electrode according to claim 9, wherein the glass particles include an oxide comprising phosphorous.

17. The paste composition for an electrode according to claim 10, wherein the glass particles include an oxide comprising phosphorous.

18. A photovoltaic cell having an electrode, wherein the electrode is formed by sintering the paste composition for an electrode according to claim 2 which is applied to a silicon substrate.

19. A photovoltaic cell having an electrode, wherein the electrode is formed by sintering the paste composition for an electrode according to claim 3 which is applied to a silicon substrate.

20. A photovoltaic cell having an electrode, wherein the electrode is formed by sintering the paste composition for an electrode according to claim 4 which is applied to a silicon substrate.

21. A photovoltaic cell having an electrode, wherein the electrode is formed by sintering the paste composition for an electrode according to claim 5 which is applied to a silicon substrate.

22. A photovoltaic cell having an electrode, wherein the electrode is formed by sintering the paste composition for an electrode according to claim 7 which is applied to a silicon substrate.

23. A photovoltaic cell having an electrode, wherein the electrode is formed by sintering the paste composition for an electrode according to claim 8 which is applied to a silicon substrate.

24. A photovoltaic cell having an electrode, wherein the electrode is formed by sintering the paste composition for an electrode according to claim 9 which is applied to a silicon substrate.

25. A photovoltaic cell having an electrode, wherein the electrode is formed by sintering the paste composition for an electrode according to claim 10 which is applied to a silicon substrate.

26. A photovoltaic cell having an electrode, wherein the electrode is formed by sintering the paste composition for an electrode according to claim 11 which is applied to a silicon substrate.

27. A photovoltaic cell having an electrode, wherein the electrode is formed by sintering the paste composition for an electrode according to claim 12 which is applied to a silicon substrate.

28. A photovoltaic cell having an electrode, wherein the electrode is formed by sintering the paste composition for an electrode according to claim 13 which is applied to a silicon substrate.

29. A photovoltaic cell having an electrode, wherein the electrode is formed by sintering the paste composition for an electrode according to claim 14 which is applied to a silicon substrate.

30. A photovoltaic cell having an electrode, wherein the electrode is formed by sintering the paste composition for an electrode according to claim 15 which is applied to a silicon substrate.

31. A photovoltaic cell having an electrode, wherein the electrode is formed by sintering the paste composition for an electrode according to claim 16 which is applied to a silicon substrate.

32. A photovoltaic cell having an electrode, wherein the electrode is formed by sintering the paste composition for an electrode according to claim 17 which is applied to a silicon substrate.
